(19) United States
(12) Patent Application Publication
(10) Pub. No.: US 2023/0036239 A1
(43) Pub. Date: Feb. 2, 2023

(54) Semiconductor Device and Method of Making an Optical Semiconductor Package

(71) Applicant: UTAC Headquarters Pte. Ltd., Singapore (SG)

(72) Inventors: Emmanuel Espiritu, Singapore (SG); Il Kwon Shim, Singapore (SG); Jeffrey Punzalan, Singapore (SG); Jose Mari Casticimo, Singapore (SG)

(73) Assignee: UTAC Headquarters Pte. Ltd., Singapore (SG)

(21) Appl. No.: 17/814,593

(22) Filed: Jul. 25, 2022

Related U.S. Application Data
(60) Provisional application No. 63/203,759, filed on Jul. 30, 2021.

(51) Int. Cl. H01L 31/0203; H01L 27/146; H01L 31/02; H01L 31/0232; H01L 31/18

(52) U.S. Cl. CPC H01L 31/0203; H01L 27/14618; H01L 27/14625; H01L 27/14632; H01L 27/14636; H01L 27/14685; H01L 27/14687; H01L 31/02005; H01L 31/02327; H01L 31/1876

(57) ABSTRACT

A semiconductor device has a substrate. A semiconductor die with a photosensitive circuit is disposed over the substrate. A lens comprising a protective layer is disposed over the photosensitive circuit. An encapsulant is deposited over the substrate, semiconductor die, and lens. The protective layer is removed after depositing the encapsulant.

### CLAIM OF DOMESTIC PRIORITY

The present application claims the benefit of U.S. Provisional Application No. 63/203,759, filed Jul. 30, 2021, which application is incorporated herein by reference.

### FIELD OF THE INVENTION

The present invention relates in general to semiconductor devices and, more particularly, to a semiconductor device and method of making an optical semiconductor package.

### BACKGROUND OF THE INVENTION

Semiconductor devices are commonly found in modern electronic products. Semiconductor devices perform a wide range of functions, such as signal processing, high-speed calculations, sensors, transmitting and receiving electromagnetic signals, controlling electronic devices, converting optical signals into electrical signals, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Optically sensitive semiconductor devices commonly have a lens or other optically transmissive lid or cover disposed over a photosensitive circuit on a semiconductor die. Packaging the semiconductor die typically includes depositing an encapsulant or molding compound around the semiconductor die while leaving the lens exposed. Preventing the lens from getting covered by encapsulant is important because the encapsulant can block light that is desired to travel through the lens.

Blocking encapsulant from over the lens is typically done by using transfer molding that applies pressure against the lens, which can damage or crack the lens. Even with the mold applying pressure against the lens, some encapsulant can still bleed onto the lens and block light. Custom molds may be used that help reduce the amount of mold bleed, but the custom molds are expensive and undesirable. Accordingly, there is a need for improvements in packaging methods and devices for optically sensitive integrated circuits.

### BRIEF DESCRIPTION OF THE DRAWINGS

FIGS. 1a-1c illustrate a semiconductor wafer with a plurality of semiconductor die separated by a saw street;

FIGS. 2a-2c illustrate forming lenses for optical semiconductor packages;

FIGS. 3a-3c illustrate lenses formed in another embodiment;

FIGS. 4a-4e illustrate a process of forming an optical semiconductor package with one of the semiconductor die and one of the lenses;

FIGS. 5a-5d illustrate forming a stepped edge in the lenses prior to forming semiconductor packages;

FIGS. 6a and 6b illustrate forming a semiconductor package by overmolding the lenses; and

FIG. 7 illustrates incorporating an optical semiconductor package into a larger electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

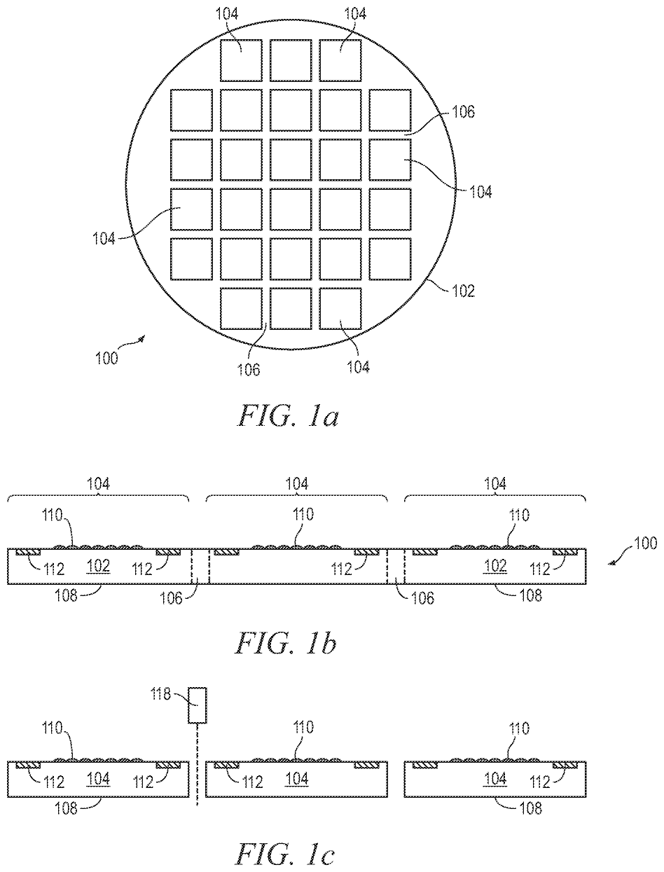

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface including a photosensitive circuit 110 and additional analog or digital circuits implemented as active devices, passive devices, conductive layers, and dielectric layers formed within the die and electrically interconnected according to the electrical design and function of the die. For example, the circuit may include one or more transistors, diodes, sensors, and other circuit elements to implement analog circuits or digital circuits, such as digital signal processor (DSP), application specific integrated circuits (ASIC), memory, or other signal processing circuit. Semiconductor die 104 may also contain integrated passive devices (IPDs), such as inductors, capacitors, and resistors, for RF signal processing. Semiconductor die 104 can implement a digital camera, luminescence sensor, or any other photosensitive device.

An electrically conductive layer 112 is formed over the active surface using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), platinum (Pt), or other suitable electrically conductive material. Conductive layer 112 operates as contact pads electrically connected to the circuits on the active surface.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known-good die (KGD) post singulation.

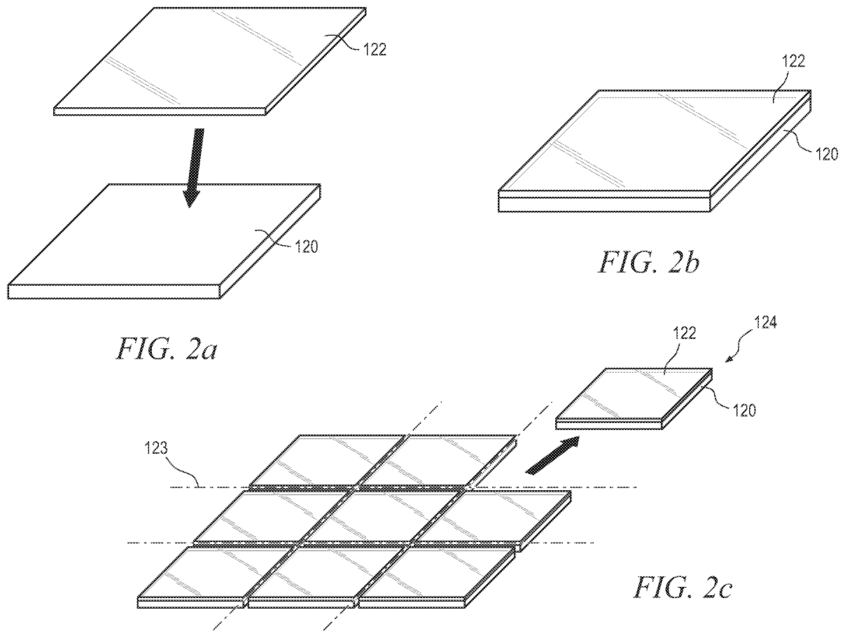

FIGS. 2a-2c illustrate preparation of lenses for use over optical semiconductor die 104 in semiconductor packages. FIG. 2a shows a sheet or plate of lens material 120. Lens material 120 is formed from glass, polymer, or another optically transparent or transmissive material. A protective tape 122 is laminated over lens material 120. Tape 122 can be any suitable material, e.g., polyimide or another polymer. In one embodiment, tape 122 is formed from a material that is able to withstand the heat of standard epoxy molding. Tape 122 optionally has a layer of thermal release adhesive that releases at or above the molding temperature of semiconductor packages being formed to ensure that the tape remains intact during the encapsulation process. FIG. 2b shows the panel of lens material 120 with tape 122 laminated thereon.

In FIG. 2c, lens material 120 is singulated into a plurality of individual lenses 124. Lenses 124 are singulated through saw streets 123 using a saw blade, laser cutting tool, or other suitable device or process. Each lens 124 has a corresponding portion of tape 122 remaining to cover the top surface of the lens.

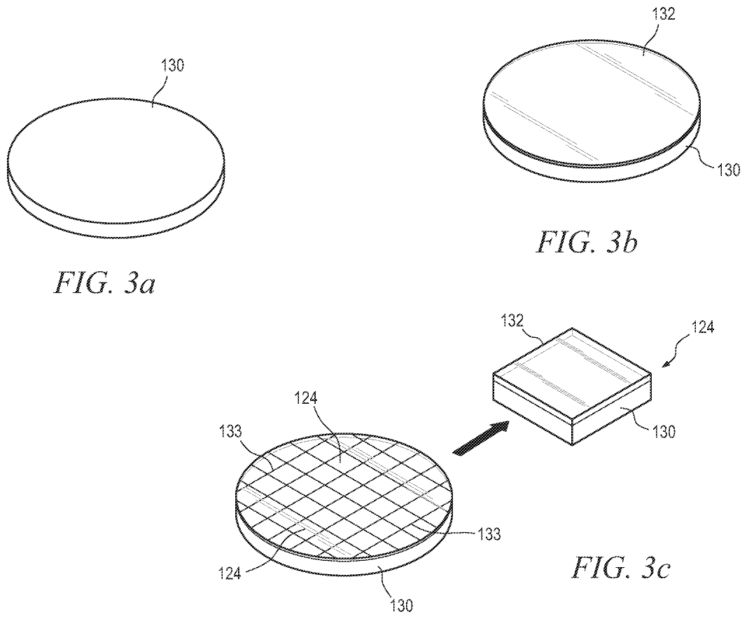

FIGS. 3a-3c illustrate forming lenses by an alternative process. FIG. 3a starts with a wafer 130 of lens material. The lens material can again be any suitable optically transmissive or transparent material, such as glass or polymer. In FIG. 3b, a protective layer 132 is formed over wafer 130. Protective layer 132 is formed using paste printing, spin coating, or another suitable process. In some embodiments, protective layer 132 is formed from a washable epoxy that is heat resistant and removable using a chemical agent or water. Protective layer 132 is applied as a liquid and then cured in one embodiment. FIG. 3c shows an individual lens 124 singulated from wafer 130 by cutting through saw streets 133 with a saw blade or laser cutting tool.

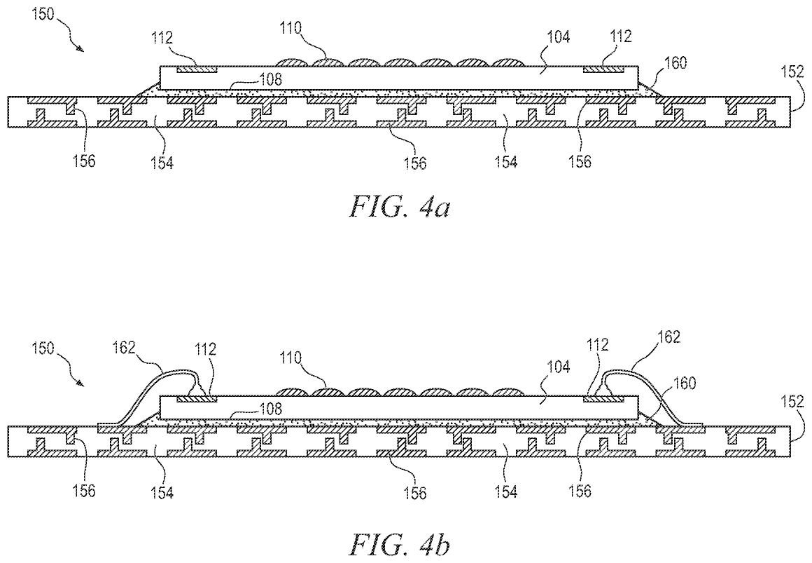

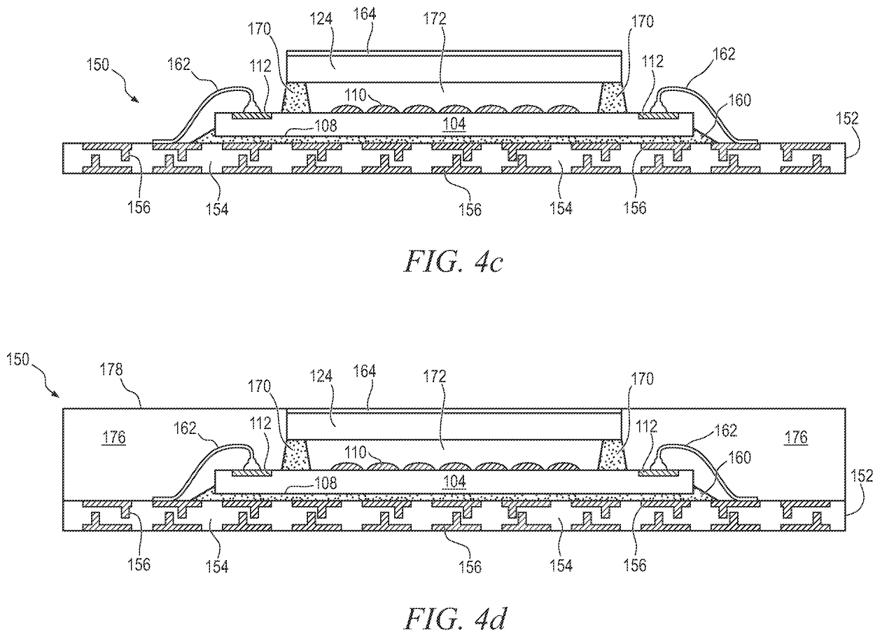

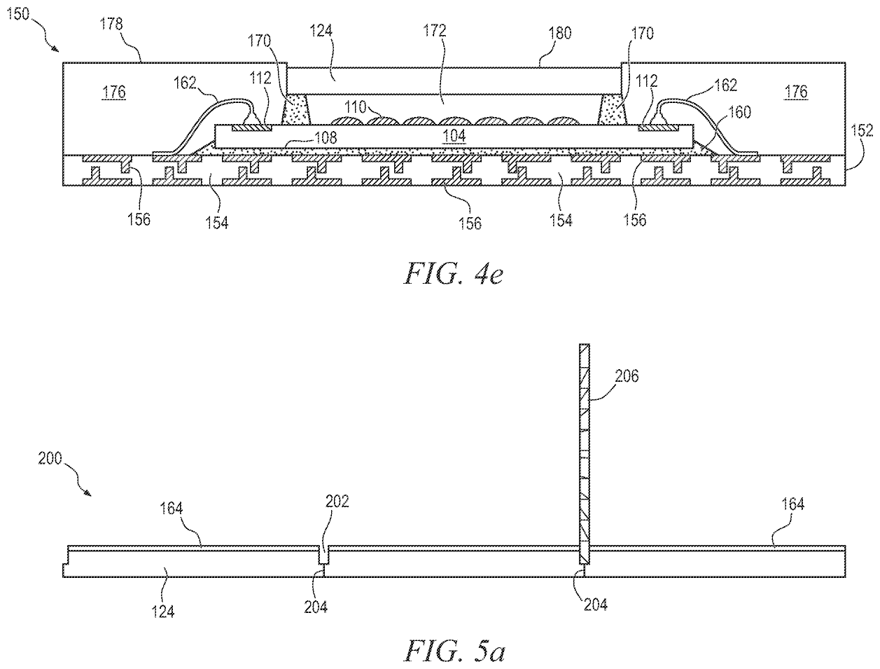

FIGS. 4a-4e illustrate a process of forming a semiconductor package 150 with semiconductor die 104. FIG. 4a shows a partial cross-sectional view of a substrate 152. While only a single substrate 152 is shown, hundreds or thousands of substrates are commonly processed on a common carrier, using the same steps described herein for a single unit but performed en masse. Substrate 152 could also start out as a single large substrate with multiple units being formed thereon, which are singulated from each other during or after the manufacturing process.

Substrate 152 includes one or more insulating layers 154 interleaved with one or more conductive layers 156. Insulating layer 154 is a core insulating board in one embodiment, with conductive layers 156 patterned over the top and bottom surfaces, e.g., a copper-clad laminate substrate. Conductive layers 156 also include conductive vias electrically coupled through insulating layers 154. Substrate 152 can include any number of conductive and insulating layers interleaved over each other. A solder mask or passivation layer can be formed over either side of substrate 152. Any suitable type of substrate or leadframe is used for substrate 152 in other embodiments.

Substrate 152 in FIG. 4a has semiconductor die 104 mounted thereon, as well as any discrete active or passive components, other semiconductor die, or other components desired for the intended functionality of semiconductor package 150. Any type and number of components can be mounted on both the top and bottom surfaces of substrate 152, or embedded within the substrate.

Semiconductor die 104 is disposed on substrate 152 using a pick-and-place process, or another suitable process or device, with photosensitive circuit 110 and contact pads 112 oriented away from the substrate. A mold underfill or other adhesive 160 is disposed on back surface 108 or substrate 152 prior to mounting semiconductor die 104. Adhesive 160 keeps semiconductor die 104 in place during the manufacturing process.

In FIG. 4b, a plurality of bond wires 162 is formed between contact pads 112 of semiconductor die 104 and contact pads of substrate 152. Bond wires 162 are mechanically and electrically coupled to conductive layer 156 of substrate 152 and to contact pads 112 of semiconductor die 104 by thermocompression bonding, ultrasonic bonding, wedge bonding, stitch bonding, ball bonding, or another suitable bonding technique. Bond wires 162 include a conductive material such as Cu, Al, Au, Ag, a metal alloy, or a combination thereof. Bond wires 162 represent one type of interconnect structure that electrically couples semiconductor die 104 to substrate 152. In other embodiments, solder bumps, conductive pillars, or another suitable interconnect structure is used. Semiconductor die 104 is a flip-chip die with photosensitive circuit 110 formed on the opposite surface from contact pads 112 in one embodiment.

In FIG. 4c, cover, lid, or lens 124 is disposed on semiconductor die 104 over photosensitive circuit 110. Lens 124 can alternatively be mounted prior to forming bond wires 162. Lens 124 can be singulated from a square or round panel with a tape or washable epoxy protective layer 164. Lens 124 has light-transmissive properties to allow an optical signal from outside of package 150 to be detected by photosensitive circuit 110. Lens 124 is formed from glass or a light-transmissive polymer in some embodiments. Lens 124 can have any combination of convex, concave, curved, domed, Fresnel, or other shaped surfaces to guide or focus light as desired. Lens 124 may also be flat as illustrated and operate primarily to physically protect photosensitive circuit 110 without significantly modifying light transmitted through the lens. Lens 124 can be totally transparent or have a material that filters one or more wavelengths of light.

Lens 124 is mounted to semiconductor die 104 over photosensitive circuit 110 using an adhesive 170. Adhesive 170 forms a continuous bead completely around the perimeter of lens 124 to protect a cavity 172 between the lens and semiconductor die 104 when encapsulant is deposited. Adhesive 170 holds lens 124 in place over photosensitive circuit 110. Adhesive 170 is deposited onto lens 124 or semiconductor die 104 prior to disposing the lens onto the semiconductor die. In one embodiment, adhesive 170 is an ultraviolet (UV) cured adhesive and protective layer 164 is a material that allows UV light to pass, thereby allowing adhesive 170 to be cured by a UV light shining through the protective layer and lens 124. In another embodiment, adhesive 170 is a thermally cured adhesive with a curing temperature that is safe for protective layer 164 so that the adhesive can be cured without damaging the protective layer.

In FIG. 4d, an encapsulant or molding compound 176 is deposited over substrate 152, semiconductor die 104, and lens 124, covering side surfaces of the lens and semiconductor die. Encapsulant 176 is an electrically insulating material deposited using a paste printing, compressive molding, transfer molding, liquid encapsulant molding, vacuum lamination, spin coating, or other suitable application process. Encapsulant 176 can be polymer composite material, such as an epoxy resin, epoxy acrylate, or polymer with or without a filler. Encapsulant 176 is non-conductive and environmentally protects the semiconductor device from external elements and contaminants.

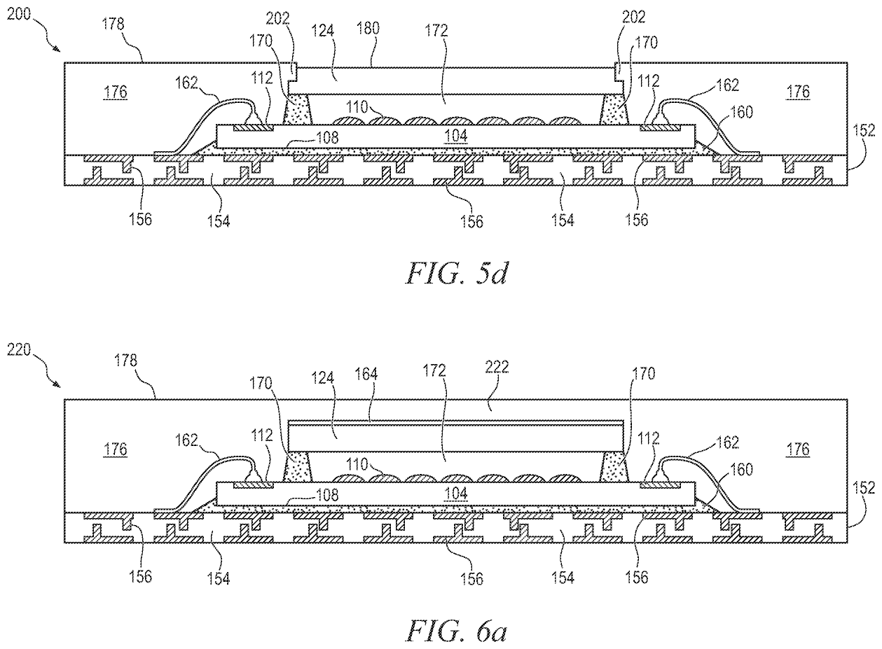

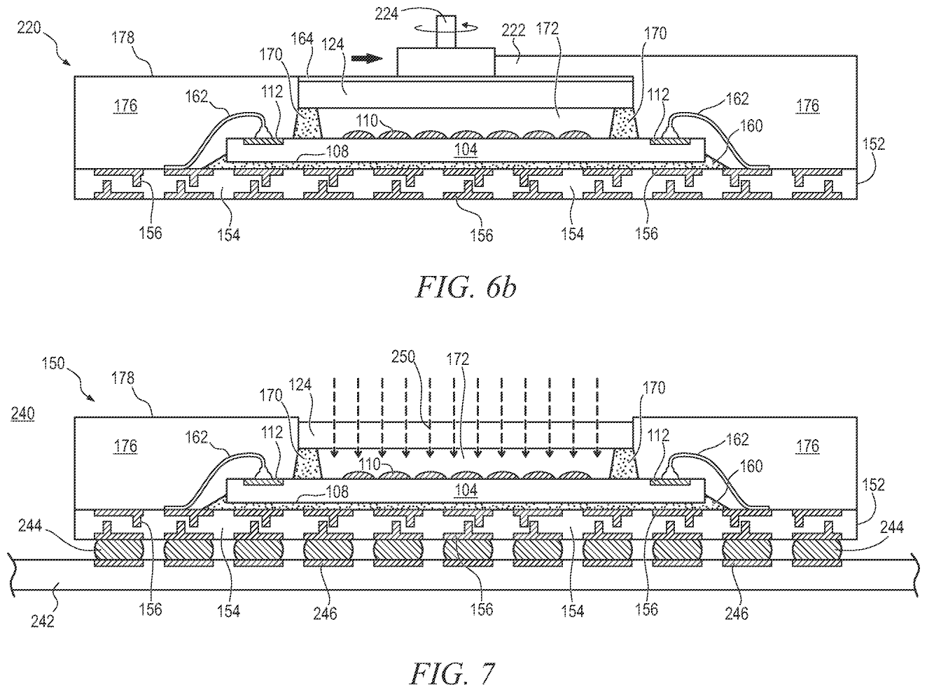

Encapsulant 176 is deposited using film-assisted molding or another method that blocks encapsulant 176 from flowing over the top of lens 124. A top surface 178 of encapsulant 176 is made coplanar to the top surface of protective layer 164, as illustrated, by the molding process. Protective layer 164 protects lens 124 during the molding process by proving a barrier or buffer between the lens and mold. A mold plate or film-assist molding film physically contacts protective layer 164 instead of lens 124. In other embodiments, as illustrated below in FIGS. 6a and 6b, encapsulant 176 is deposited over lens 124 and then removed.

Adhesive 170 blocks encapsulant 176 from flowing between lens 124 and semiconductor die 104. Encapsulant 176 is typically deposited with substrate 152 remaining as a larger panel with multiple semiconductor packages 150 being formed at once. The larger panel of substrate 152 and encapsulant 176 is then singulated into individual units after manufacturing is complete.

In FIG. 4e, protective layer 164 is removed in a process appropriate for the type of protective layer used. Protective layer 164 is removed by peeling if tape 122 is used or washing if washable epoxy 132 is used. In other embodiments, protective layer 164 is chemically dissolved, etched, or otherwise removed using any suitable process. In one embodiment, protective layer 164 adheres to the film-assist molding film and is removed as an inherent step of the molding process, e.g., when a thermal release film is used for protective layer 164. An additional adhesive can be applied on the film-assist molding film or onto protective layer 164 for molding, which helps remove the protective layer as part of the molding process and also helps seal the surface of the protective layer 164 against encapsulant seepage during molding.

Removal of protective layer 164 also removes any encapsulant 176 that happened to seep onto lens 124 during the molding process, greatly reducing the risk of malfunction due to encapsulant seeping onto the lens. A top surface 180 of lens 124 is recessed relative to top surface 178 of encapsulant 176 after the protective layer 164 is removed. Solder bumps are optionally disposed over the bottom surface substrate 152 before or after removing protective layer 164. If a plurality of semiconductor packages 150 remains as a larger panel, then the semiconductor packages are singulated from each other using a saw blade or laser cutting tool.

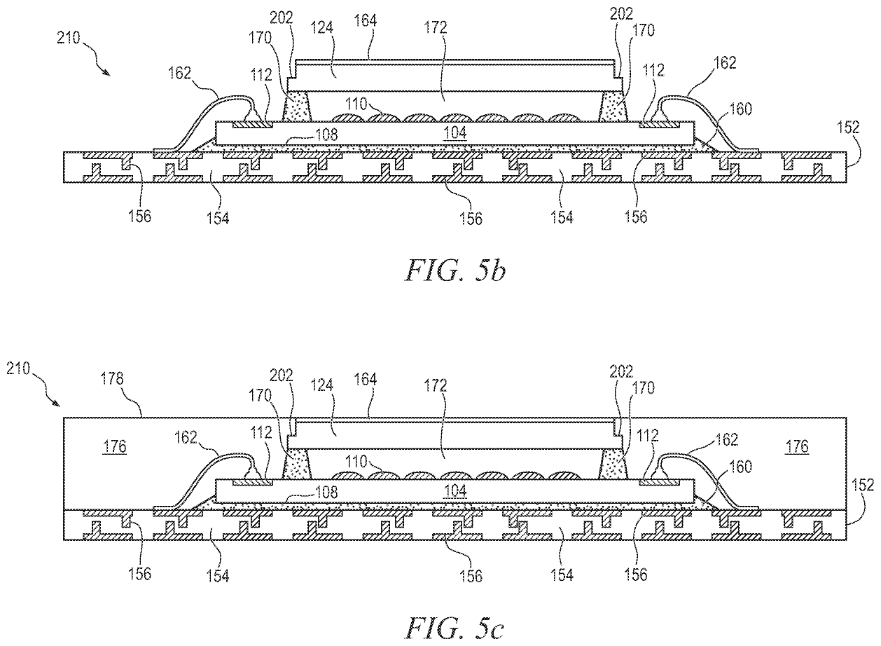

FIGS. 5a-5d show an alternative embodiment with a lens having notched or stepped outer edges. In FIG. 5a, panel 200 of lens material has grooves 202 formed along saw streets 204 using a saw blade 206. Panel 200 can be a circular or rectangular panel as shown in FIGS. 2a and 3a. Other shapes are used in other embodiments. Protective layer 164 can be any of the embodiments discussed above.

Grooves 202 run completely around the perimeter of each lens 124 so that the step cut extends completely around each lens. In other embodiments, not every edge of each lens 124 has a step cut from grooves 202 being formed, e.g., only two opposing edges of each lens have a step cut in one embodiment.

Grooves 202 extend completely through protective layer 164 and only partially through lenses 124. Lenses 124 remain connected to each other at saw streets 204 before the lenses are singulated from each other as shown in FIGS. 2c and 3c. Saw blade 206 has a wider kerf than the blade that will singulate panel 200 into lenses 124, so that the resulting lenses have edges with a portion of groove 202 remaining as a step cut.

FIG. 5b shows formation of semiconductor packages 210 with a lens 124 having a step cut with one side of groove 202 remaining on one or more edges of the lens. Lens 124 is mounted to semiconductor die 104 over photosensitive circuit 110 with adhesive 170 as above. Protective layer 164 remains to protect lens 124 during the molding process.

FIG. 5c shows encapsulant 176 deposited over substrate 152, semiconductor die 104, and lens 124 as described above. Encapsulant 176 fills in the area around lens 124 above grooves 202. The result of lens 124 being step-cut with groove 202 is that the opening in top surface 178 of encapsulant 176 is smaller than the widest width of lens 124. The reduced size of the opening in surface 178 helps keep lens 124 trapped within encapsulant 176. Encapsulant 176 applies a force against the top surface of lens 124 within groove 202 that tends to hold the lens in place to a greater degree than without the step cut where only vertical surfaces of the lens and encapsulant contact each other at the edges of the lens. In FIG. 5d, protective layer 164 is removed as described above, resulting again in surface 180 of lens 124 recessed relative to surface 178 of encapsulant 176.

FIGS. 6a and 6b show overmolding lens 124. Encapsulant 176 is deposited over substrate 152, semiconductor die 104, and lens 124 as in FIGS. 4d and 5c. However, encapsulant 176 is deposited to completely cover lens 124 in FIG. 6a, with portion 222 of the encapsulant formed directly over the lens. Protective layer 164 remaining properly in place on lens 124 prevents direct physical contact between the top surface of the lens and encapsulant 176.

In FIG. 6b, a portion of encapsulant 176, including portion 222, is removed by mechanical grinding with grinder 224, chemical-mechanical planarization (CMP), chemical etching, or another suitable process to expose protective layer 164. Protective layer 164 operates as an etch-stop layer in some embodiments. Overmolding eliminates physical contact between the chase mold and lens 124 with protective layer 164 during molding, thus reducing the likelihood of damage and the number of parameters that must be considered for the manufacturing process. Protective layer 164 is removed after planarization to leave lens 124 recessed below surface 178 of encapsulant 176.

FIG. 7 illustrates integrating the above-described semiconductor packages, e.g., semiconductor package 150, into a larger electronic device 240. FIG. 7 is a partial cross-section of package 150 mounted onto a printed circuit board (PCB) or other substrate 242 as part of electronic device 240.

Bumps 244 are formed over the bottom of substrate 152 at any stage in the manufacturing process, typically as a final step before singulation. A conductive bump material is deposited over substrate 152 opposite semiconductor die 104 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads of conductive layer 156 using a suitable attachment or bonding process. The bump material can be reflowed by heating the material above its melting point to form conductive balls or bumps 244.

In one embodiment, conductive bumps 244 are formed over an under-bump metallization (UBM) having a wetting layer, barrier layer, and adhesion layer. Conductive bumps 244 can also be compression bonded or thermocompression bonded to conductive layer 156. Conductive bumps 244 represent one type of interconnect structure that can be formed over substrate 152 for electrical connection to a larger electrical system. The interconnect structure can also use bond wires, conductive paste, stud bump, micro bump, conductive pillars, or another type of electrical interconnect. In other embodiments, contact pads of conductive layer 156 remain exposed as a land-grid array.

Bumps 244 are reflowed onto conductive layer 246 of PCB 242 to physically attach and electrically connect semiconductor package 150 to the PCB. In other embodiments, thermocompression or other suitable attachment and connection methods are used. In some embodiments, an adhesive or underfill layer is used between package 150 and PCB 242. Semiconductor die 104 is electrically coupled to conductive layer 246 through substrate 152 to allow use of the functionality of package 150 to the larger system.

Electronic device 240 can have one type of semiconductor package, or multiple types of semiconductor packages, depending on the application. Electronic device 240 can be a stand-alone system that uses the semiconductor packages to perform one or more electrical functions. Alternatively, electronic device 240 can be a subcomponent of a larger system. For example, electronic device 240 can be part of a tablet computer, cellular phone, digital camera, communication system, or other electronic device. Package 150 can operate as, e.g., a camera or luminescence sensor for electronic device 240, converting light rays 250 into a sensor reading or photographic image.

Semiconductor packages 150 are manufactured with a higher yield due to the use of protective layer 164. Optical packages can be molded with standard chase molds, with or without film assisted molding, which prevents increased costs commonly associated with forming a non-standard mold chase for optical packages.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor die;
disposing a lens including a protective layer over the semiconductor die;
depositing an encapsulant over the semiconductor die and lens; and
removing the protective layer after depositing the encapsulant.

2. The method of claim 1, further including laminating the protective layer onto the lens.

3. The method of claim 1, wherein the protective layer includes a washable epoxy.

4. The method of claim 1, further including removing the encapsulant from over the lens prior to removing the protective layer.

5. The method of claim 1, further including:
mounting the lens to the semiconductor die with an ultraviolet (UV) cured adhesive; and
curing the adhesive by emitting a UV light through the lens.

6. The method of claim 1, further including forming a step cut on an edge of the lens.

7. A method of making a semiconductor device, comprising:
providing a lens including a protective layer;
depositing an encapsulant over the lens; and
removing the protective layer after depositing the encapsulant.

8. The method of claim 7, further including laminating the protective layer onto the lens.

9. The method of claim 7, wherein the protective layer includes a washable epoxy.

10. The method of claim 7, further including removing the encapsulant from over the lens prior to removing the protective layer.

11. The method of claim 7, further including:
providing a substrate;
disposing a semiconductor die comprising a photosensitive circuit over the substrate;
disposing the lens over the photosensitive circuit; and
depositing the encapsulant over the substrate, semiconductor die, and lens.

12. The method of claim 11, further including:
mounting the lens to the semiconductor die with an ultraviolet (UV) cured adhesive; and
curing the adhesive by emitting a UV light through the lens.

13. The method of claim 7, further including forming a step cut on an edge of the lens.

14. The method of claim 13, further including depositing the encapsulant over the step cut.

15. A semiconductor device, comprising:
a substrate;
a semiconductor die including a photosensitive circuit disposed over the substrate;
a lens disposed over the semiconductor die; and
an encapsulant deposited over the substrate, semiconductor die, and lens, wherein the lens is recessed within the encapsulant.

16. The semiconductor device of claim 15, wherein the lens includes a step cut.

17. The semiconductor device of claim 15, further including a protective layer formed over the lens.

18. The semiconductor device of claim 17, wherein a surface of the protective layer is coplanar to a surface of the encapsulant.

19. The semiconductor device of claim 17, wherein the encapsulant covers a top surface of the protective layer.

20. The semiconductor device of claim 17, wherein the protective layer includes a washable epoxy.
